(19) United States
(12) Patent Application Publication
(10) Pub. No.: US 2026/0040989 A1
(43) Pub. Date: Feb. 5, 2026

(54) SELECTIVELY FORMED BOND PAD STRUCTURE

(71) Applicant: TEXAS INSTRUMENTS INCORPORATED, DALLAS, TX (US)

(72) Inventors: JOMARI AUSTRIA, MALABON CITY (PH); JEFFREY SOLAS, ILOILO CITY (PH); RAY FREDRIC DE ASIS, MABALACAT (PH)

(21) Appl. No.: 18/790,999

(22) Filed: Jul. 31, 2024

(51) Int. Cl. H01L 23/00; H01L 21/56

(52) U.S. Cl. CPC H01L 24/05; H01L 21/565; H01L 24/03; H01L 24/04; H01L 24/48; H01L 2224/03462; H01L 2224/03515; H01L 2224/04042; H01L 2224/05247; H01L 2224/05647; H01L 2224/48225; H01L 2924/1815

(57) ABSTRACT

A method of forming an integrated circuit (IC) package includes electroplating a seed layer in a first electroplating process to form a polycrystalline copper layer of a bond pad structure of an IC structure over an active circuit region of the IC structure. The method also including electroplating over the polycrystalline copper layer in a second electroplating process, different than the first electroplating process, to form a nanotwin copper layer of the bond pad structure. The method further including attaching a bond wire to the nanotwin copper layer of the bond pad structure to form a copper-to-copper bond between the bond wire and the nanotwin copper layer of the bond pad structure.

### TECHNICAL FIELD

This description relates to a dual electroplating process for forming a bond pad structure for wire bonding.

### BACKGROUND

A bond pad is a small area or pad on the surface of an integrated circuit (IC) package that is designed for the attachment of external electrical connections, sometimes in the form of bond wires. These external connections are used to link the IC package to other components, such as other IC packages, PCBs (printed circuit boards) or other parts of an electronic system. Bond pads facilitate the proper functioning of integrated circuits because bond pads provide a path for electrical signals to enter and exit the IC package. Bond pads are typically formed of metal and are located on the topmost layer of a die of the IC package.

### SUMMARY

One example relates to a method of forming an integrated circuit (IC) package. The method includes electroplating a seed layer in a first electroplating process to form a polycrystalline copper layer of a bond pad structure of an IC structure over an active circuit region of the IC structure. The method also including electroplating over the polycrystalline copper layer in a second electroplating process, different than the first electroplating process, to form a nanotwin copper layer of the bond pad structure. The method further including attaching a bond wire to the nanotwin copper layer of the bond pad structure to form a copper-to-copper bond between the bond wire and the nanotwin copper layer of the bond pad structure.

Another example relates to a method of forming an IC package. The method includes electroplating a wafer in a first electroplating process to form a polycrystalline copper layer of a bond pad structure. The method also includes electroplating over the polycrystalline copper layer in a second electroplating process, different than the first electroplating process, to form a nanotwin copper layer of the bond pad structure. The method further includes singulating a die from the wafer. The die comprises the bond pad structure. The method includes mounting the die on an interconnect. The method also includes attaching a bond wire to the bond pad structure to form a copper-to-copper bond between the bond wire and the bond pad structure.

Yet another example relates to an IC package. The IC package includes a circuit on a device side of a die and a bond pad structure formed over the circuit. The bond pad structure having a polycrystalline copper layer. The bond pad structure also includes a discontinuous passivation layer formed over the polycrystalline copper layer. The discontinuous passivation layer includes an opening. The bond pad structure further includes a nanotwin copper layer formed over the discontinuous passivation layer and in contact with the polycrystalline copper layer through the opening.

### BRIEF DESCRIPTION OF THE DRAWINGS

FIG. 1 illustrates a cross-section view of an integrated circuit (IC) package that includes a bond pad structure for wire bonding over active circuits.

FIG. 2 illustrates an expanded view of a region that includes a copper-to-copper (Cu—Cu) bond between a bond pad structure and a bond wire of FIG. 1.

FIG. 3 illustrates a top view of an IC package having selectively formed bond pad structures.

FIG. 4 illustrates a current graph depicting plating operations for a direct electroplating process of polycrystalline copper.

FIG. 5 illustrates a current graph depicting plating operations for a pulsed electroplating process of nanotwin copper.

FIGS. 6-21 illustrate operations of a method for forming an IC package with a bond pad structure.

FIG. 22 illustrates a flowchart of an example method for fabricating an IC package with a bond pad structure.

### DETAILED DESCRIPTION

In semiconductor industries, demands for miniaturization have accelerated the development of smaller integrated devices. As the pitch size is reduced, a passivation layer is used to provide stability and protection for bond pad structures. The passivation layer is cured at high temperatures greater than 350° C. This may be acceptable for bond structures using costly metals, such as palladium, but can prevent less costly materials from being present during the curing of the passivation layer. For example, nanotwin copper is less costly than palladium, but the structure of nanotwin copper suffers at the high temperatures used to cure the passivation layer. Specifically, at high temperatures, nanotwin copper reverts to a polycrystal structure that diminishes its diffusivity characteristics which enable direct copper-to-copper (Cu—Cu) bonding.

A dual electroplating process is described herein that prevents nanotwin copper from reverting to a polycrystal structure. In the dual electroplating process, the passivation layer is cured after a polycrystalline copper layer is plated but before nanotwin copper layer is plated. By curing the passivation layer prior to plating the nanotwin copper, the structure of the nanotwin copper is preserved allowing direct copper-to-copper bonding. The resulting bond pad structure includes a passivation layer sandwiched between a polycrystalline copper layer and a nanotwin copper layer.

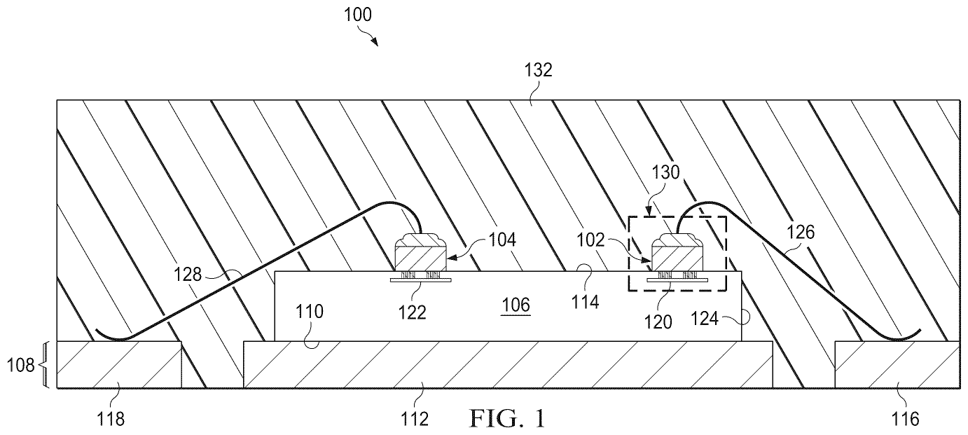

FIG. 1 illustrates a cross-section view of an IC package 100 that includes a first bond pad structure 102 and a second bond pad structure 104. The IC package 100 includes a die 106 mounted on an interconnect 108. More specifically, a first side 110 of the die 106 is mounted on a die attach pad 112 of the interconnect 108. A second side 114 of the die 106 opposes the first side 110 of the die 106. Moreover, the first bond pad structure 102 and a second bond pad structure 104 are situated on the second side 114 of the die 106. In some examples, the interconnect 108 is alternatively referred to as a lead frame. The interconnect 108 includes a first lead 116 and a second lead 118. In other examples, there are more or fewer leads on the interconnect 108.

The first bond pad structure 102 is coupled to a first circuit 120 (e.g., a circuit module) embedded in the die 106 and the second bond pad structure 104 is coupled to a second circuit 122 (e.g., a circuit module) embedded in the die 106. In the example illustrated, the first bond pad structure 102 is proximate to an edge 124 of the die 106. For simplification, it is presumed that the edge 124 of the die 106 forms a periphery of the die 106. Conversely, in the illustrated example, the second bond pad structure 104 is proximate to a center region of the die 106 and distal to the edge 124. However, in other examples, the second bond pad structure 104 is proximate to the edge 124 of the die 106. In some examples, the first bond pad structure 102 and/or the second bond pad structure 104 are implemented as BOAC (bond over active circuit) connections to the respective first circuit 120 and/or second circuit 122.

The first lead 116 is connected to the first bond pad structure 102 with a first bond wire 126. The second lead 118 is connected to the second bond pad structure 104 with a second bond wire 128. The first bond wire 126 and the second bond wire 128 are formed with copper wires that have a diameter between about 17.78 micrometers (μm) and about 50.8 μm. The first bond pad structure 102 and the second bond pad structure 104 are formed with copper (Cu). Thus, the first bond wire 126 and the first bond pad structure 102 form a Cu—Cu bond. In a similar manner, the second bond wire 128 and the second bond pad structure 104 form a Cu—Cu bond. To ensure a high rate of diffusion and to strengthen the Cu—Cu bond of the first bond wire 126 and the second bond wire 128, the respective uppermost layers of the first bond pad structure 102 and the second bond pad structure 104 are formed of nanotwin copper (ntCu). The bond pad structures 102, 104 include a ntCu layer and a polycrystalline copper layer partially separated by a discontinuous passivation layer.

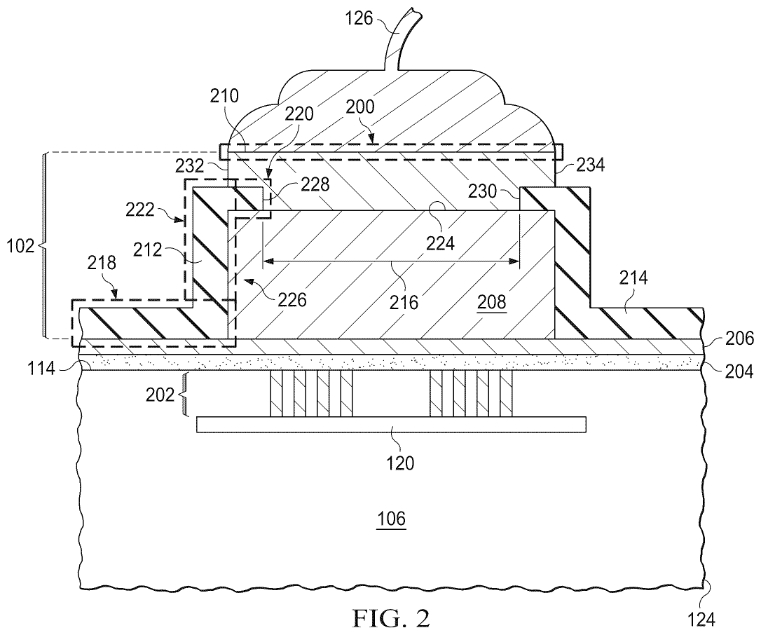

FIG. 2 illustrates an expanded view of a region 130 that includes the Cu—Cu bond between the first bond pad structure 102 and the first bond wire 126. Thus, FIGS. 1 and 2 employ the same reference numbers to denote the same features.

In FIG. 2, a Cu—Cu bond 200 is formed between the first bond pad structure 102 and the first bond wire 126. The first bond pad structure 102 includes a number of layers formed over the first circuit 120. A number of vias 202 provide an electrical connection from the first circuit 120 to the first bond pad structure 102. The number of vias 202 are formed of an electrically conductive material, such as copper, palladium, gold, silver, or other appropriate conductive metal or metal alloys with similar properties. In some examples, the vias 202 are formed through an insulating layer formed over the die 106.

The first bond pad structure 102 includes an adhesion layer 204. The adhesion layer 204 may include metals which have good adhesion. In some examples, the adhesion layer 204 adheres to the insulating layer. For example, the adhesion layer 204 is formed of titanium (Ti) or titanium-tungsten (TiW) and is formed by a sputter process. The first bond pad structure 102 may also include a seed layer 206 formed over the adhesion layer 204. The seed layer 206 provides a suitable electrically conductive surface for a subsequent electroplating operation. The seed layer 206 may include nickel (Ni) or copper (Cu), for example, and be formed by a sputter process or an evaporation process.

The first bond pad structure 102 includes a multi-layer conductive contact electrically coupled to the first circuit 120. The multi-layer conductive contact includes a plurality of different metal layers including a polycrystalline copper layer 208 and a ntCu layer 210. The polycrystalline copper layer 208 is formed of multiple instances of a crystal lattice structure plated in a first electroplating process of a dual electroplating process. The crystal lattice structure has a Miller index of (100). The ntCu layer 210 is formed of a continuous pattern plated in a second electroplating process of the dual electroplating process. The continuous pattern of the ntCu layer 210 increases diffusivity of the ntCu structure. The ntCu layer 210 including the crystal lattice with the Miller indices of (111).

The polycrystalline copper layer 208 and ntCu layer 210 are partially separated by a discontinuous passivation layer. The passivation layer is formed of an insulating material such as a polyimide, a silicone, an epoxy, an elastomer, a polymer, or other suitable material. The passivation layer includes a first passivation portion 212 and a second passivation portion 214 separated by an opening 216. In the example illustrated, the second passivation portion 214 is proximate to an edge 124 of the die 106. The first passivation portion 212 is distal to the edge 124. The passivation portions 212, 214 include horizontal segments separated by a vertical segment. For example, the first passivation portion 212 has a first horizontal segment 218 and a second horizontal segment 220 separated by a vertical segment 222. The first horizontal segment 218 extends longitudinally along the seed layer 206 proximate the die 106. The second horizontal segment 220 extends longitudinally along an upper surface 224 of the polycrystalline copper layer 208 distal to the die 106. The vertical segment 222 extends from the first horizontal segment 218 to the second horizontal segment 220. The vertical segment 222 extends adjacent a contact sidewall 226 of the polycrystalline copper layer 208 to the second horizontal segment 220.

The ntCu layer 210 contacts the upper surface 224 of the polycrystalline copper layer 208 at the opening 216 in the passivation layer. A bond pad structure interface between the polycrystalline copper layer 208 and the ntCu layer 210 is formed at the upper surface 224. Due to the opening 216 in the passivation layer, about 75% to 95% of the upper surface 224 of the polycrystalline copper layer 208 contacts the ntCu layer 210. The ntCu layer 210 has a first lower sidewall 228 and a second lower sidewall 230 opposite the first lower sidewall 228. The first lower sidewall 228 and the second lower sidewall 230 are formed by the first passivation portion 212 and the second passivation portion 214 respectively. The ntCu layer 210 also has a first upper sidewall 232 and a second upper sidewall 234 that extend over the first passivation portion 212 and the second passivation portion 214 respectively. Accordingly, the distance between the upper sidewalls 232, 234 is greater than the distance between the lower sidewall 228, 230, giving the ntCu layer 210 a T-shape. While the ntCu layer 210 is described as having a T-shape, the ntCu layer 210 may have any shape based on the geometry of the opening 216 in the passivation layer. For example, if the second horizontal segments, such as the second horizontal segment 220 have angled ends, curved ends, etc., then the ntCu layer 210 has corresponding angled ends, curved ends, etc. respectively.

Referring back to FIG. 1, the IC package 100 is encapsulated with a mold compound 132. In some examples, the mold compound 132 is a plastic. By implementing dual electroplating process, the continuous pattern of the ntCu layer 210 is preserved thereby maintaining the increased diffusivity of the ntCu structure which enables the Cu—Cu bond 200. The Cu—Cu bond 200 obviates the need for expensive materials such as Pd.

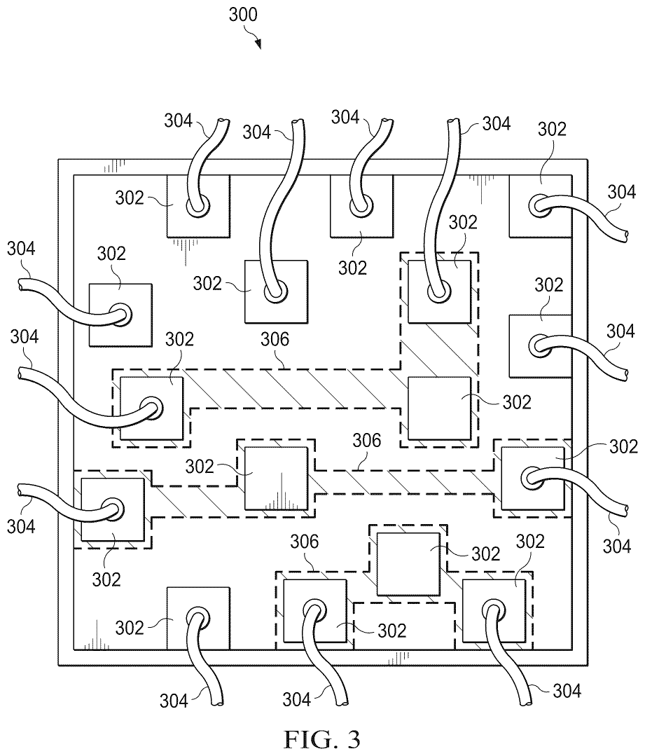

FIG. 3 illustrates a top view of an IC package having selectively formed bond pad structures. The IC area 300 includes a number of bond pad structures 302 (e.g., the bond pad structures 102, 104 of FIG. 1) and corresponding bond wires 304 (e.g., bond wires 126, 128 of FIG. 1. The bond pad structures 302 have a ntCu layer (e.g., the ntCu layer 210 of FIG. 2) overlaying a polycrystalline copper layer (e.g., the polycrystalline copper layer 208 of FIG. 2). The interface between the bond pad structures 302 and corresponding bond wires 304 form a Cu—Cu bond (e.g., the Cu—Cu bond 200 of FIG. 2).

A number of the bond pad structures 302 are connected by lines 306. For example, a number of bond pad structures 302, which supply power current to the active IC, are combined into several power distribution lines 306. Because the lines 306 conduct current but are not bonded to another structure, the lines 306 do not undergo Cu—Cu bonding. Accordingly, the lines 306 are formed of the polycrystalline copper layer. Thus, the ntCu layer is selectively plated at the bond pad structures 302 of the IC area 300 that benefit from the ntCu structure having higher diffusivity than a polycrystal structure.

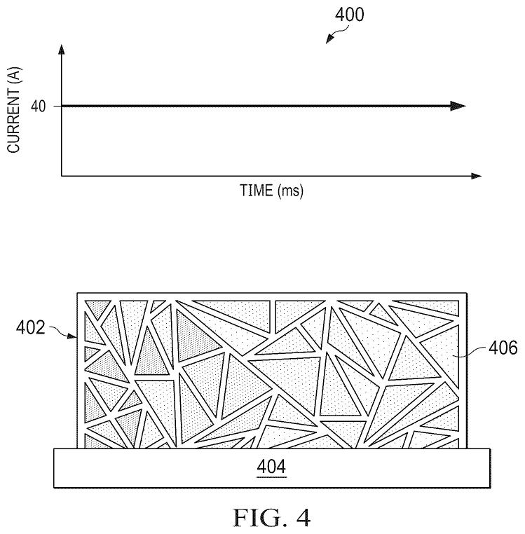

FIG. 4 illustrates a first graph 400 depicting plating operations for a direct electroplating process of polycrystalline copper. More particularly, the first graph 400 is a current graph depicting a direct plating operation for electroplating. The first graph 400 plots a direct current, in amperes (A) as a function of time, in millisecond (ms) employed to form a polycrystal structure 402. In the example illustrated, a wafer 404 is immersed in a solution with a copper concentration of about 32 grams per liter (g/L) or about 55 g/L. The direct current of about 40 A is applied to the wafer 404 in solution to form the polycrystal structure 402. The polycrystal structure 402 includes copper grains 406 with crystal structures having Miller indices of (100).

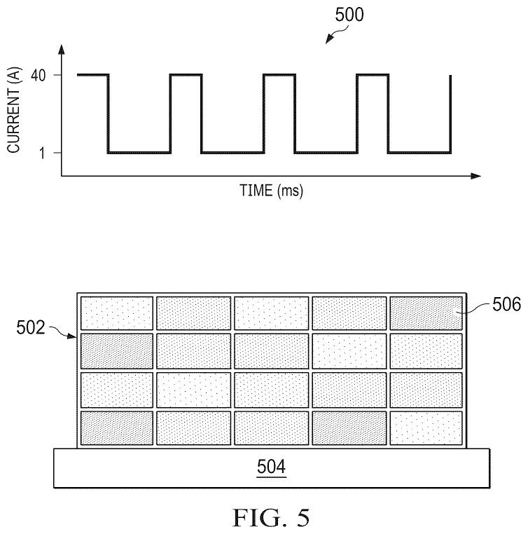

In FIG. 5, a current graph 500 depicts a pulsed plating operation for electroplating. The current graph 500 also plots a pulsed current, in A as a function of time in ms employed to form a ntCu structure 502. In the example illustrated, the pulsed current is pulsed at a frequency of about 5 to about 10 hertz (Hz) between current of about 40 A and a current less than 1 A. The pulsed current has a duty cycle of about 25% in some examples. In the example illustrated, it is presumed that a wafer 504 is immersed in a solution with a copper concentration of about 32 g/L or about 55 g/L. It is understood that in other examples other concentrations are employable, such as copper concentrations between 30 g/L and 60 g/L. In examples where the 25% duty cycle is used, and the solution has a copper concentration of 32 g/L, the pulsed plating can be applied for about 22 minutes to form a plating that is about 10 μm thick. Thus, the pulsed plate rate in this situation is about 0.45 μm per minute (μm/min). In examples where the 25% duty cycle is used, and the solution has a copper concentration of 55 g/L, the pulsed plating can be applied for about 10 minutes to form a plating that is about 10 μm thick. Thus, the pulsed plate rate in this situation is about 1.0 μm/min.

The dual electroplating process includes a first electroplating process, such as the direct electroplating process of FIG. 4 and a second electroplating process, such as the pulsed electroplating process of the FIG. 5. The direct electroplating process forms a polycrystalline copper layer (e.g., the polycrystalline copper layer 208 of FIG. 2) of a bond pad structure (e.g., the bond pad structures 102, 104 of FIG. 1), the polycrystalline layer having a polycrystal structure (e.g., the polycrystal structure 402 of FIG. 4). The pulsed electroplating process forms an ntCu layer (e.g., the ntCu layer 210 of FIG. 2) of the bond pad structure, the ntCu layer having an ntCu structure 502 with Miller indices of (111). The ntCu structure 502 provides a high rate of atom diffusion, enabling the Cu—Cu bond (e.g., the Cu—Cu bond 200 of FIG. 2) at the interface of the ntCu structure 502.

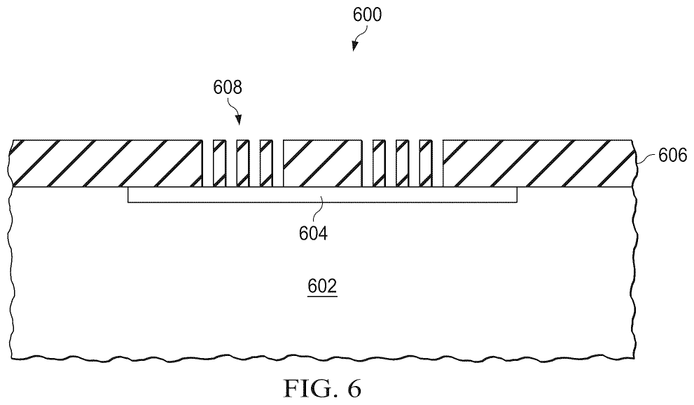

FIGS. 6-21 illustrate operations of a method for forming an IC package with a copper bond pad, such as the IC package 100 of FIG. 1. For purposes of simplification, FIGS. 6-21 employ the same reference numbers to denote the same structure.

FIG. 6 illustrates an example of a first stage of a process flow of fabricating a selectively formed bond pad structure. A wafer 600 includes semiconductor die 602 having an active circuit 604 (e.g., the circuits 120, 122 of FIG. 1) formed on a device side thereof. An insulating layer 606 includes a number of voids 608. As one example, the voids 608 are formed in the insulating layer 606 by etching the insulating layer 606 using a photomask or photoresist layer. For clarity, formation of a single bond pad structure with respect to the die 602 is described, however, the stages and methods may be used to form any number of bond pad structures for an IC package. Moreover, any number of dies may be fabricated on the wafer 600.

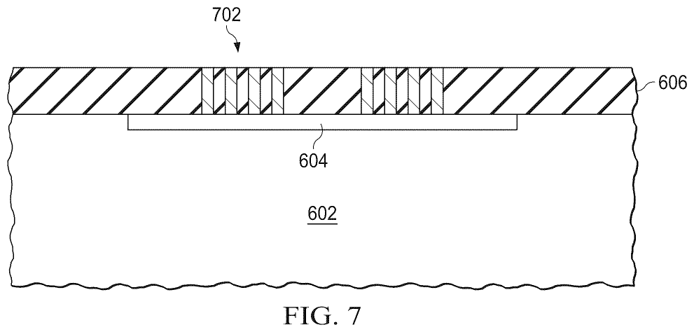

FIG. 7 illustrates an example of a second stage of the process flow. In the second stage, the voids 608 are filled with a conductive material to form vias 702 (e.g., the vias 202 of FIG. 2). For example, the conductive material is Cu. As one example, the voids 608 are filled with the conductive material using a deposition or sputtering process.

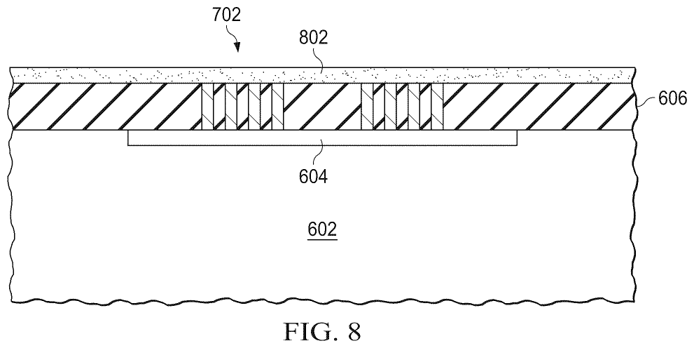

FIG. 8 illustrates an example of a third stage of the process flow. In the third stage, an adhesion layer 802 (e.g., the adhesion layer 204 of FIG. 2) is applied over the insulating layer 606 having the vias 702. For example, the adhesion layer 802 is formed by a sputter process or an evaporation process. In some examples, the adhesion layer 802 is formed of titanium (Ti) or titanium-tungsten (TiW) that is sputtered over the insulating layer 606 on the wafer 600. For example, the titanium is co-sputtered with tungsten over the epoxy resin of the insulating layer 606.

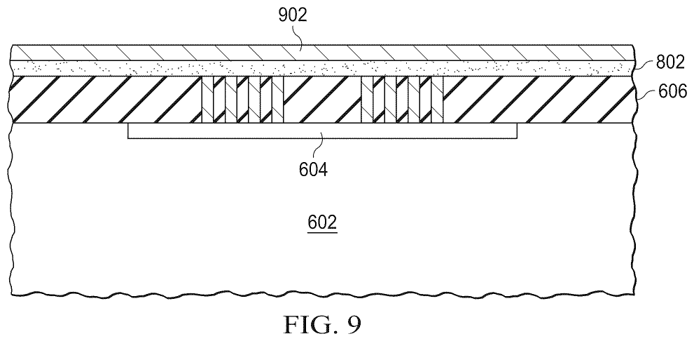

FIG. 9 illustrates an example of a fourth stage of the process flow. In the fourth stage, a seed layer 902 (e.g., the seed layer 206 of FIG. 2) is formed by sputtering a seed metal material over the adhesion layer 802. The seed layer 902 provides an electrically conductive surface for a subsequent electroplating operation. In some examples, the seed metal material of the seed layer 9902 includes Cu based on the metal material being used to form a bond pad structure.

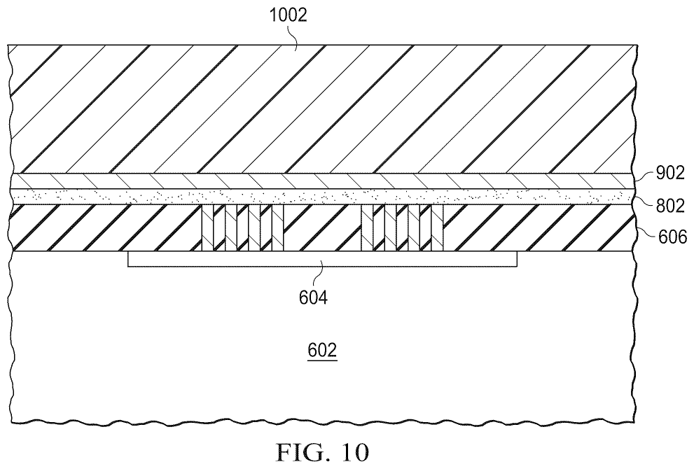

FIG. 10 illustrates an example of a fifth stage of the process flow. In the fifth stage, a photoresist layer 1002 is formed on the seed layer 902, such as by spin coating or another application method. The photoresist layer 1002 is formed of a photoresist material that is a light-sensitive material.

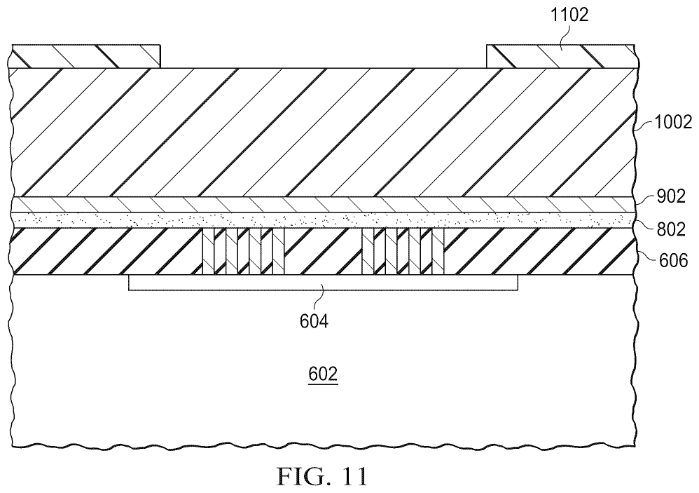

FIG. 11 illustrates an example of a sixth stage of the process flow. In the sixth stage, a photomask 1102 is applied to the photoresist layer 1002 and the photoresist layer 1002 and the photomask 1102 are irradiated selectively. Portions of the photoresist layer 1002 that are obscured by the photomask 1102 are nonirradiated portions.

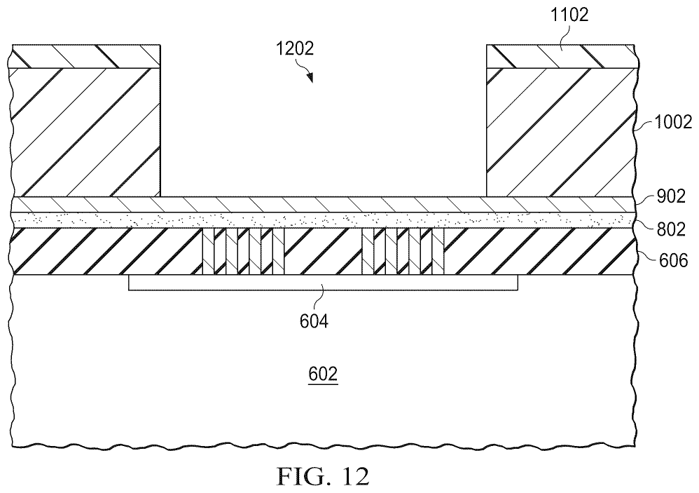

FIG. 12 illustrates an example of a seventh stage of the process flow. In the seventh stage, the photomask 1102 and the irradiated portions are removed from the photoresist layer 1002 (e.g., by an etch process) leaving a void 1202. For example, a development process is performed on the photomask 1102 and the irradiated portions of the photoresist layer 1002 to form the void 1202.

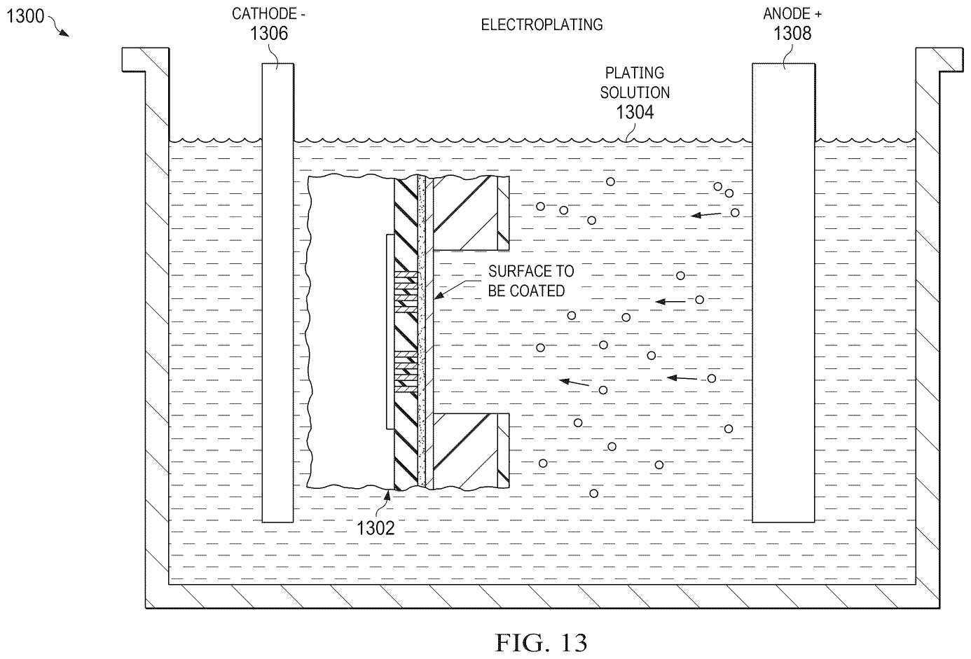

FIG. 13 illustrates an example of an eighth stage of the process flow. In the eighth stage, a first electroplating process 1300 is performed to form a polycrystalline copper structure in the void 1202. The wafer 1302, having the layers (e.g. adhesion layer 802, the seed layer 902, the photoresist layer 1002, etc.) of the previous stages) applied to the wafer 600, is immersed in a first plating solution 1304 with a copper concentration of about 32 grams per liter (g/L) or about 55 g/L. In the illustrated example, the wafer 1302 is coupled to a cathode 1306 and faces an anode 1308. A direct current of about 40 A is applied to the wafer 1302 to form the polycrystalline structure (e.g., the polycrystal structure 402 of FIG. 4).

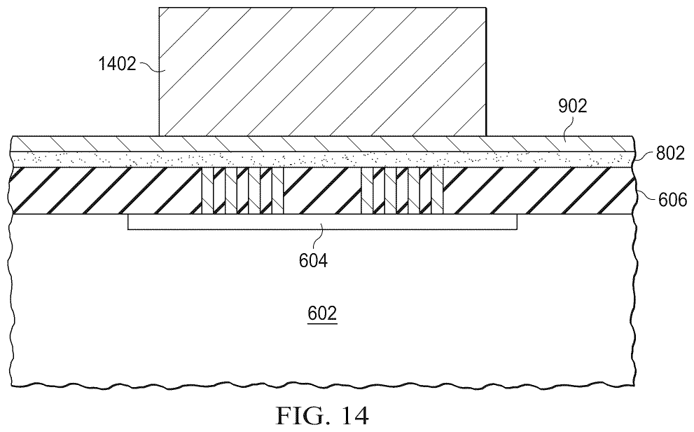

FIG. 14 illustrates an example of a ninth stage of the process flow. In the ninth stage, the wafer 1302 is removed from the first plating solution 1304 with the polycrystalline copper layer 1402 (e.g., the polycrystalline copper layer 208 of FIG. 2). In some examples, the wafer 1302 undergoes acid washing with solution and rinsing with deionized water.

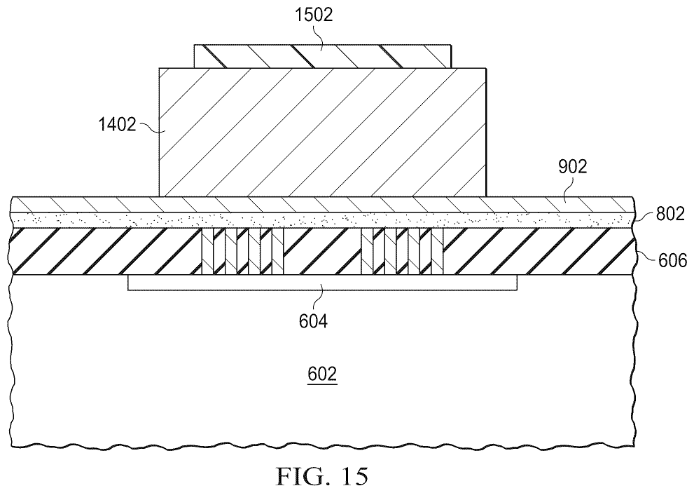

FIG. 15 illustrates an example of a tenth stage of the process flow. In the tenth stage, a photoresist layer 1502 is formed on the polycrystalline copper layer 1402, such as by spin coating or another application method. The photoresist layer 1502 is formed of a photoresist material that is a light-sensitive material.

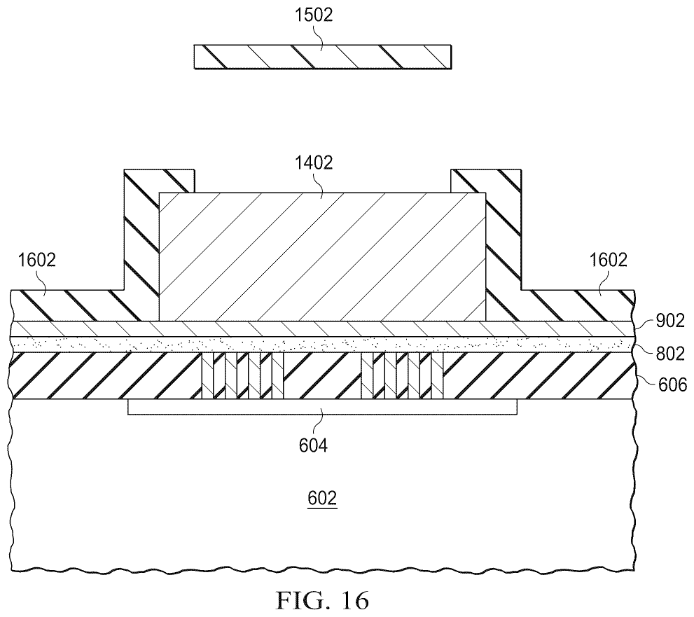

FIG. 16 illustrates an example of an eleventh stage of the process flow. In the eleventh stage, a passivation layer 1602 is applied and the photoresist layer 1502 is removed. For example, the passivation layer 1602 is placed using a spin-coating process. The passivation layer 1602 is discontinuous including passivation portions (e.g., a first passivation portion 212 and a second passivation portion 214 of FIG. 2) separated by the photoresist layer 1502. In response to the passivation layer 1602 being applied, the photoresist layer 1502 is removed. An opening (e.g., the opening 216 of FIG. 2) is formed in the passivation layer 1602 as a consequence of the photoresist layer 105 being removed. The passivation layer 1602 has a first passivation portion (e.g., the first passivation portion 212 of FIG. 2) and a second passivation portion (e.g., the second passivation portion 214 of FIG. 2) separated by the opening.

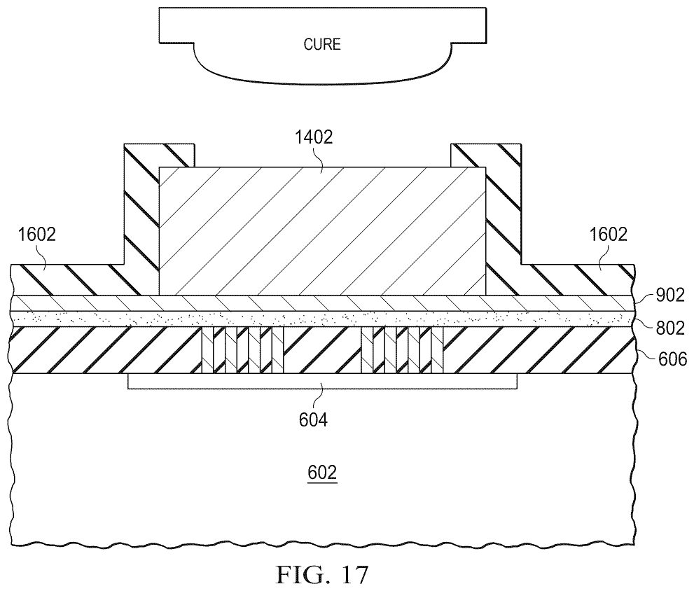

FIG. 17 illustrates an example of a twelfth stage of the process flow. In the twelfth stage, the passivation layer 1602 is cured. In some examples, the passivation layer 1602 is cured to be a stable polyimide film. For example, the passivation layer 1602 is cured at temperatures of approximately 250° C. to 450° C. for about one to two hours to form a cured passivation layer.

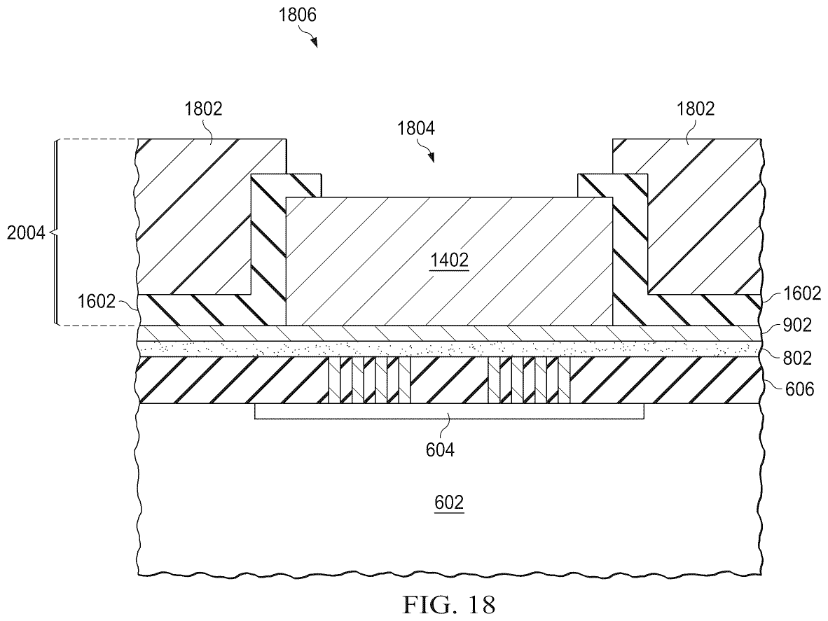

FIG. 18 illustrates an example of a thirteenth stage of the process flow. In the thirteenth stage, a photoresist layer 1802 is applied over the first passivation portion and the second passivation portion to form a void 1804. The photoresist layer 1802 is formed of a photoresist material that is a light-sensitive material to form a patterned coating on a surface. Accordingly, a wafer 1806, having layers (e.g. adhesion layer 802, the seed layer 902, the photoresist layer 1002, polycrystalline copper layer 1402, passivation layer 1602, a photoresist layer 1802) is formed.

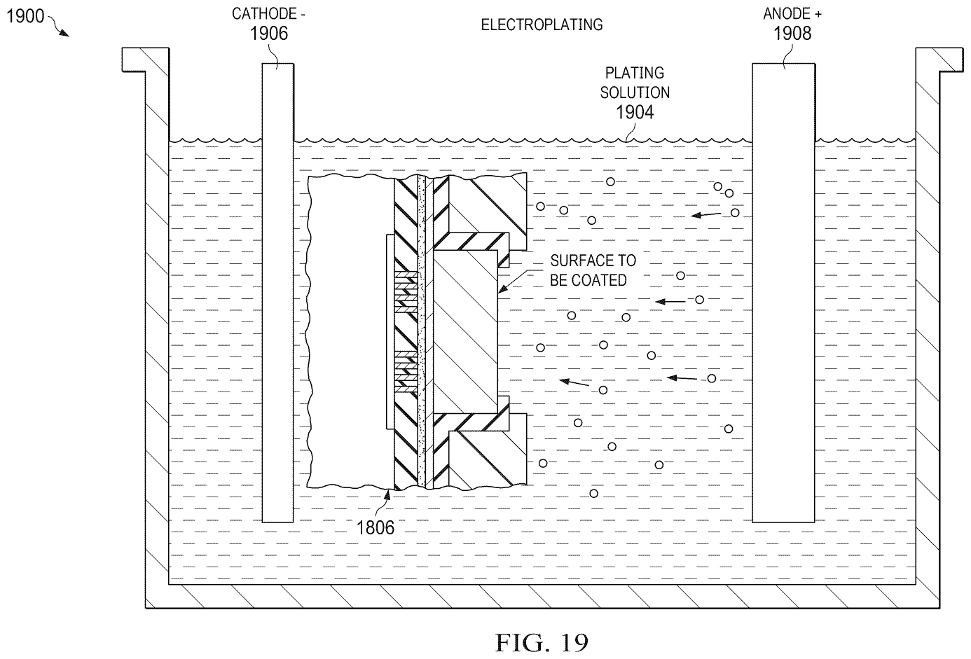

FIG. 19 illustrates an example of a fourteenth stage of the process flow. In the fourteenth stage, a second electroplating process 1900 is performed to form a ntCu copper structure in the void 1804. The wafer 1806 is immersed (e.g., submerged) in a second plating solution 1904 different than the first plating solution 1304. For example, the second plating solution 1904 ma with a copper concentration of between 30 g/L and 60 g/L, such as a copper concentration of about 32 g/L or 55 g/L, and include an additive to promote growth of copper grains (e.g., the copper grains 506 of FIG. 5) that have crystal lattice structures with Miller indices of (111).

The wafer 1806 is coupled to a cathode 1906 and faces an anode 1908. A pulsed plating operation is executed for electroplating a ntCu structure onto the wafer 1806. The pulsed current, in A as a function of time in milliseconds employed to form the ntCu structure (e.g., the ntCu structure 502 of FIG. 5). In the example illustrated, a current through the anode 1908 is pulsed at a frequency of about 5 to about 10 Hz between current of about 40 A and a current less than 1 A, forming a waveform similar to the waveform depicted in the current graph 500 of FIG. 5. The pulsed current has a duty cycle of about 25% in some examples.

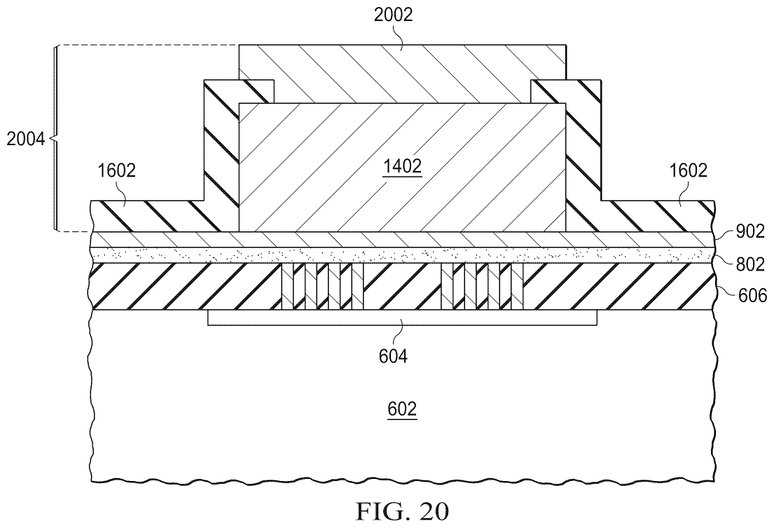

FIG. 20 illustrates an example of a fifteenth stage of the process flow. In the fifteenth stage, the wafer 1806 is removed from the second plating solution 1904 with the ntCu layer 2002 (e.g., the ntCu layer 210 of FIG. 2). In some examples, portions of the ntCu layer 2002 are removed by etching and/or photolithography techniques to form patterns of the bond pad structure 2004. Additionally, in examples where photolithography techniques are used, a photoresist is applied on the wafer to form the patterns for the copper bond pads and exposed to light a specific frequency range. Subsequently, remaining photoresist is stripped. In some examples, a coating of anti-tarnish is applied to the bond pad structure 2004 to impede corrosion of the ntCu layer 2002. In such situations, the anti-tarnish coating is applied responsive to the electroplating operation.

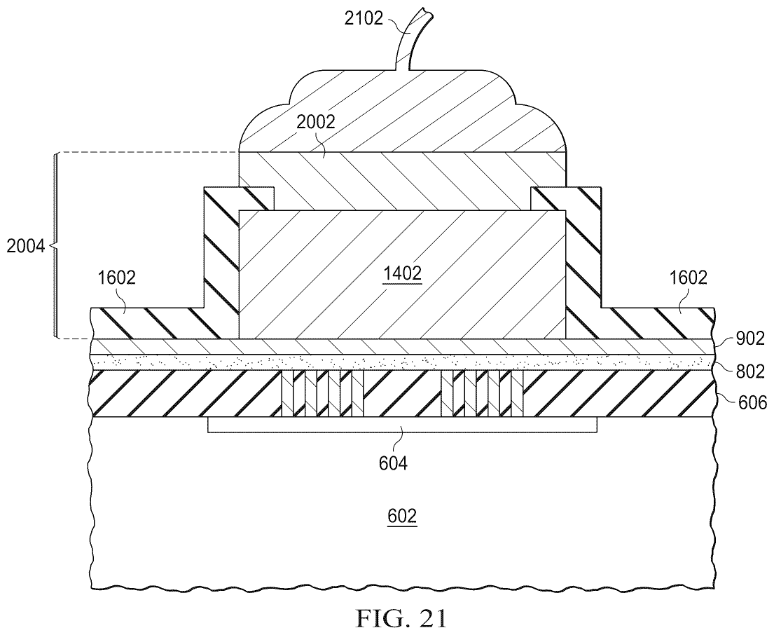

As illustrated in FIG. 21, in a sixteenth stage, a bond wire 2102 is attached to the ntCu layer 2002. Because ntCu layer 2002 and the bond wire 2102 are formed with copper, the bond wire 2102 forms a copper-to-copper (Cu—Cu) connection with the bond pad structure.

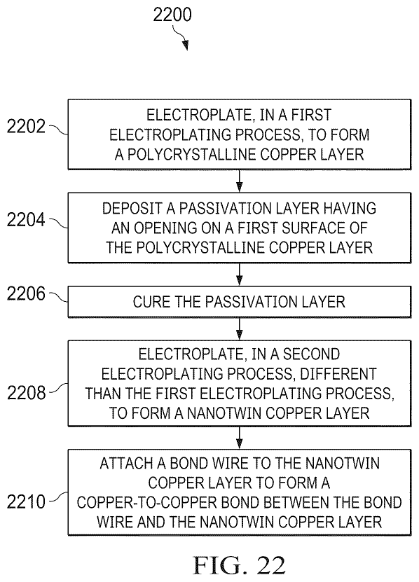

FIG. 22 illustrates a flowchart of an example method 2200 for fabricating an IC package with bond pad structure, such as the IC package 100 of FIG. 1.

At block 2202, a first electroplating process is performed. In the first electroplating process, a wafer, such as the wafer 1302 of FIG. 13 is immersed (e.g., submerged) in a first plating solution (e.g., the first plating solution 1304) with a copper concentration of between 30 g/L and 60 g/L, such as a copper concentration of about 32 g/L or 55 g/L. The first electroplating process is a direct plating operation. The direct plating operation is executed to induce a direct current between an anode (e.g., the anode 1308 of FIG. 13) and a cathode (e.g., the cathode of FIG. 1306 of FIG. 13) immersed in the first plating solution. The direct current of about 40 A is applied to the wafer to form a polycrystalline layer (e.g., the polycrystalline copper layer 208 of FIG. 2, the polycrystalline copper layer 1402 of FIG. 14) having the polycrystal structure (e.g., the polycrystal structure 402 of FIG. 4).

At block 2204, a passivation layer (e.g., the passivation layer 1602 of FIG. 16) is deposited having an opening on a first surface of the polycrystalline copper layer opposite a second surface of the polycrystalline copper layer.

At block 2206, the passivation layer the passivation layer is cured. For example, the passivation layer is formed of polyimide. The passivation layer is cured at temperatures of approximately 200° C. to 450° C. for about one to two hours forming a cured passivation layer.

At block 2208, a second electroplating process is performed. In the second electroplating process, a wafer, such as the wafer 1806 of FIG. 19. In the second electroplating process, the wafer is immersed (e.g., submerged) in a second plating solution (e.g., the second plating solution 1904 of FIG. 19) different than the first plating solution. The second plating solution may have a copper concentration of between 30 g/L and 60 g/L, and an additive to promote growth of copper grains (e.g., the copper grains 506 of FIG. 5) that have crystal lattice structures with Miller indices of (111). The second electroplating process is a pulsed plating operation is executed to induce a pulsed current between an anode (e.g., the anode 1908 of FIG. 19) and a cathode (e.g., the cathode 1906 of FIG. 19) immersed in the second plating solution. As one example, the pulsed current is pulsed at a frequency of about 5 to about 10 Hz with a duty cycle of about 25%-50% between current of about 40 A and a current less than 1 A.

At block 2210, a bond wire (e.g., the first bond wire 126 of FIG. 1, the second bond wire 128 of FIG. 1, the bond wires 304 of FIG. 3, the bond wire 2102 of FIG. 21) is attached to the bond pad structure (e.g., the first bond pad structure 102 and the second bond pad structure 104 of FIG. 1, the bond pad structure 2004 of FIG. 20). Because the copper bond pad is formed with copper, the bond wire forms a copper-to-copper (Cu—Cu) connection with the copper bond pad. In some examples, the wafer is singulated to form a number of dies. The singulation is executed with a saw, such as a laser saw, a plasma cutter or a diamond saw. Further, a mold compound (e.g., the mold compound 132 of FIG. 1) encapsulates the die and the interconnect in a mold flow operation.

Accordingly, the method 2200 describes a dual electroplating process, having a first electroplating process and a second electroplating process, to form a bond pad structure. The first electroplating process forms a polycrystalline layer of the bond pad structure and the second electroplating process forms a nanotwin (ntCu) layer of the bond pad structure. Thus, the dual electroplating process obviates the need for expensive materials such as Pd for the bond pad structure.

The passivation layer is deposited and cured after the first electroplating process but before the second electroplating process. By curing the passivation layer prior to forming the ntCu layer, the nanotwin copper structure of the ntCu layer is preserved. The nanotwin copper structure has diffusivity characteristics that enable direct Cu—Cu bonding between the ntCu layer and the bond wire.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming an integrated circuit (IC) package, comprising:
electroplating a seed layer in a first electroplating process to form a polycrystalline copper layer of a bond pad structure of an IC structure over an active circuit region of the IC structure;
electroplating over the polycrystalline copper layer in a second electroplating process, different than the first electroplating process, to form a nanotwin copper layer of the bond pad structure; and
attaching a bond wire to the nanotwin copper layer of the bond pad structure to form a copper-to-copper bond between the bond wire and the nanotwin copper layer of the bond pad structure.

2. The method of claim 1, further comprising:
depositing a passivation layer having an opening on a first surface of the polycrystalline copper layer opposite a second surface of the polycrystalline copper layer, wherein the second surface of the polycrystalline copper layer is in contact with the seed layer; and
curing the passivation layer before the second electroplating process to form a cured passivation layer having the opening.

3. The method of claim 2, wherein the nanotwin copper layer is in contact the polycrystalline copper layer through the opening in the cured passivation layer.

4. The method of claim 1, wherein the first electroplating process is a direct electroplating process that applies a direct current to the bond pad structure immersed in a plating solution.

5. The method of claim 1, wherein the second electroplating process is a pulse electroplating process that applies a pulsed current to the bond pad structure immersed in a plating solution.

6. The method of claim 5, wherein the pulsed current has a duty cycle of about 25%.

7. The method of claim 5, wherein the pulsed current has a frequency of about 5 hertz.

8. The method of claim 1, wherein the nanotwin copper layer of the bond pad structure is formed with copper grains that have a crystal lattice structure with Miller indices of 111.

9. The method of claim 1, further comprising encapsulating the IC structure and the bond wire in a mold compound.

10. A method of forming an integrated circuit (IC) package, comprising:
electroplating a wafer in a first electroplating process to form a polycrystalline copper layer of a bond pad structure;
electroplating over the polycrystalline copper layer in a second electroplating process, different than the first electroplating process, to form a nanotwin copper layer of the bond pad structure;
singulating a die from the wafer, wherein the die comprises the bond pad structure;
mounting the die on an interconnect; and
attaching a bond wire to the bond pad structure to form a copper-to-copper bond between the bond wire and the bond pad structure.

11. The method of claim 10, further comprising:
depositing a passivation layer having an opening on a first surface of the polycrystalline copper layer opposite a second surface of the polycrystalline copper layer, wherein the second surface of the polycrystalline copper layer is in contact with the wafer; and
curing the passivation layer before the second electroplating process to form a cured passivation layer having the opening.

12. The method of claim 11, wherein the nanotwin copper layer is in contact the polycrystalline copper layer through the opening in the cured passivation layer.

13. The method of claim 10, wherein the first electroplating process is a direct electroplating process that applies a direct current to the bond pad structure immersed in a plating solution.

14. The method of claim 10, wherein the second electroplating process is a pulse electroplating process that applies a pulsed current to the bond pad structure immersed in a plating solution.

15. An integrated circuit (IC) package, comprising:
a circuit on a device side of a die; and
a bond pad structure formed over the circuit, the bond pad structure having:
a polycrystalline copper layer,
a discontinuous passivation layer formed over the polycrystalline copper layer, the discontinuous passivation layer having an opening, and
a nanotwin copper layer formed over the discontinuous passivation layer and in contact with the polycrystalline copper layer through the opening.

16. The IC package of claim 15, wherein the nanotwin copper layer of the bond pad structure is formed with copper grains that have a crystal lattice structure with Miller indices of 111.

17. The IC package of claim 15, wherein the opening in the discontinuous passivation layer forms a bond pad structure interface between the polycrystalline copper layer and the nanotwin copper layer at a first surface of the polycrystalline copper layer, wherein about 75% to 95% of the first surface of the polycrystalline copper layer contacts the nanotwin copper layer.

18. The IC package of claim 15, further comprising:
a bond wire coupled to the bond pad structure and to a lead of an interconnect, wherein the bond wire and the bond pad structure form a copper-to-copper bond.

19. The IC package of claim 18, further comprising:
a mold compound encapsulating the die, the interconnect and the bond wire.

20. The IC package of claim 15, wherein the bond pad structure is a BOAC (bond over active circuit) connection.
